(19) United States
(12) Patent Application Publication
(10) Pub. No.: US 2013/0077012 A1
(43) Pub. Date: Mar. 28, 2013

(54) SEMICONDUCTOR DEVICE AND METHOD FOR MANUFACTURING THE SAME, AND LIQUID CRYSTAL DISPLAY DEVICE

(71) Applicant: Kenshi Tada, Osaka-shi (JP)

(72) Inventor: Kenshi Tada, Osaka-shi (JP)

(21) Appl. No.: 13/702,313

(22) PCT Filed: May 24, 2011
(86) PCT No.: PCT/JP2011/002885

§ 371 Date: Dec. 6, 2012

(30) Foreign Application Priority Data
Jul. 8, 2010 (JP) 2010-155464

(51) Int. Cl. G02F 1/1362; H01L 29/786

(52) U.S. Cl. CPC G02F 1/136286; H01L 29/78678
USPC 349/43; 257/71; 438/158

(57) ABSTRACT

A semiconductor device includes a gate electrode formed on an insulating substrate, a gate insulating film covering the gate electrode, a semiconductor layer formed on a surface of the gate insulating film and having a channel region facing the gate electrode, and an electrode layer connected to the semiconductor layer. An island-shaped interlayer insulating film covering the channel region is formed on a surface of the semiconductor layer. An end portion of the interlayer insulating film is interposed between the semiconductor layer and the electrode layer. Outer edges of the interlayer insulating film are located further inside than respective corresponding outer edges of the semiconductor layer by the same width, as viewed in a normal direction of a surface of the insulating substrate. The electrode layer is connected to an end portion of the semiconductor layer.

### TECHNICAL FIELD

The present invention relates to semiconductor devices and methods for manufacturing the semiconductor device, and liquid crystal display devices.

### BACKGROUND ART

A thin film transistor (TFT) including an amorphous silicon (a-Si:H) film as the active layer can be formed on a large-area substrate at low temperature, and therefore, is applied to semiconductor devices, such as a liquid crystal display etc. In recent years, there has been a display employing a TFT including, as the active layer, a polycrystalline silicon (poly-Si) film which is formed at low temperature, in order to reduce the power consumption of the display. On the other hand, there is a demand for a reduction in the cost of the device. To meet the demand, PATENT DOCUMENT 1 proposes a method for manufacturing a semiconductor device in which the number of masks is reduced to reduce the photo steps.

In the manufacturing method described in PATENT DOCUMENT 1, an inverted staggered TFT is formed as follows. A metal film forming a source electrode and a drain electrode, and another metal film which is formed by the same process as that of that metal film, are used as a doping mask to dope a semiconductor layer with an impurity. A contact region is formed in the impurity doped region. Thereafter, a transparent conductive film having a pattern is formed. The transparent conductive film is used as a mask to selectively remove a portion of the doping mask which faces the channel region of the semiconductor layer and is not inherently required for a source electrode layer or a drain electrode layer.

The transparent conductive film is in contact with an upper surface of the contact region and covers entire upper surfaces of the metal layers of the source and drain electrodes. As a result, the formation of the TFT requires the following four photo steps: a gate electrode formation step; a Si layer pattern formation step; a drain/source pattern formation step; and an ITO pattern and channel region formation step. Therefore, the manufacturing cost can be reduced.

### CITATION LIST

### Patent Document

PATENT DOCUMENT 1: Japanese Patent Publication No. H08-88368

### SUMMARY OF THE INVENTION

### Technical Problem

Here, FIG. 43 is a cross-sectional view showing a configuration of the above conventional TFT 100. FIG. 44 is a plan view showing a region where a source line and a gate line intersect. FIG. 45 is a cross-sectional view taken along line XXXXV-XXXXV of FIG. 44.

As shown in FIG. 43, the TFT 100 includes a gate electrode 102 formed on a glass substrate 101, a gate insulating film 103 of SiN covering the gate electrode 102, and a semiconductor layer 104 of Si formed on the gate insulating film 103. The semiconductor layer 104 has a channel region 110 facing the gate electrode 102, contact regions (high-concentration impurity regions) 111 formed on opposite sides of the channel region 110, and side regions 112 formed on outer sides the contact regions 111.

On the glass substrate 101, a drain/source electrode layer 105 overlapping the side regions 112 is formed, and an ITO interconnect layer 107 overlapping the drain/source electrode layer 105 is formed. End portions of the ITO interconnect layer 107 are connected to the contact region 111.

On the other hand, as shown in FIGS. 44 and 45, a gate line 120 and a drain/source line 108 intersecting the gate line 120 are formed on the glass substrate 101. The gate insulating film 103 and the semiconductor layer 104 formed on the gate insulating film 103 are formed on the glass substrate 101, covering the gate line 120. A portion of the semiconductor layer 104 is covered by the drain/source line 108. The drain/source line 108 is covered by the ITO interconnect layer 107.

However, in the above conventional semiconductor device, the reduction of the photo steps has an adverse effect.

Specifically, by using the drain/source electrode layer 105 as a mask, a photo step of ion doping is removed. However, in order to form the mask, the side regions 112, which are not involved in the operation of the TFT 100, need to be formed at outer end portions of the semiconductor layer 104. As a result, a width D of the semiconductor layer 104 increases, and therefore, it becomes more difficult to reduce the size of the TFT 100.

FIG. 7(b) of PATENT DOCUMENT 1 shows a configuration in which the drain/source electrode layer 105 is not formed in the side regions 112, although not shown. In the configuration, the contact region 111 is connected to the drain/source electrode layer 105 via the ITO interconnect layer 107, which has a high resistance, on the contact region 111, and therefore, the on-current characteristics of the TFT 100 unavoidably deteriorate. In addition, the drain/source electrode layer 105 needs to be formed outside the regions of the TFT 100 and the semiconductor layer 104, and therefore, it is difficult to reduce the size of the TFT 100 including the drain/source line layer.

A metal pattern (the drain/source electrode layer 105) serving as a mask is formed directly on the channel region 110 of the semiconductor layer 104, and therefore, the channel region is likely to be contaminated by a metal. Moreover, when the metal pattern is etched to expose the channel region 110, a surface of the semiconductor layer 104 in the channel region 110 is also etched, and therefore, the characteristics of the TFT 100 deteriorate, disadvantageously resulting in an increase in leakage current.

In addition, when the contact region (high-concentration impurity region) 111 is thermally activated, a low temperature treatment is required in order to avoid excessive silicidation which is caused by reaction of the metal pattern with silicon contained in the semiconductor layer 104, disadvantageously resulting in a deterioration in the characteristics of the TFT 100.

The ITO interconnect is connected is connected to the contact region 111 directly or via an unstable surface metal layer (e.g., a low-temperature formed surface silicide layer, such as a MOSi layer, etc.). Therefore, it is difficult to achieve a stably low contact resistance.

Moreover, it is difficult to reduce the capacitance of an intersection portion which is formed by the gate line and the source/drain line intersecting each other. The relatively large capacitance leads to an increase in signal delay and power consumption. Although polycrystallization is described, CMOS is not taken into consideration. PATENT DOCUMENT 1 describes activation of the impurity implanted into the semiconductor layer by laser irradiation. However, it is difficult to perform laser irradiation without an influence on the lower gate layer or the drain/source electrode layer.

The present invention has been made in view of the above problems. It is a main object of the present invention to provide a semiconductor device which has a smaller size and stable characteristics.

### Solution to the Problem

To achieve the object, a semiconductor device according to the present invention includes a gate electrode formed on an insulating substrate, a gate insulating film covering the gate electrode, a semiconductor layer formed on a surface of the gate insulating film and having a channel region facing the gate electrode, and an electrode layer connected to the semiconductor layer. An island-shaped interlayer insulating film covering the channel region is formed on a surface of the semiconductor layer. An end portion of the interlayer insulating film is interposed between the semiconductor layer and the electrode layer. Outer edges of the interlayer insulating film are located further inside than respective corresponding outer edges of the semiconductor layer by the same width, as viewed in a normal direction of a surface of the insulating substrate. The electrode layer is connected to an end portion of the semiconductor layer.

A method for manufacturing a semiconductor device according to the present invention includes the steps of forming a gate electrode having a predetermined shape on an insulating substrate, forming and stacking a first insulating material layer, a semiconductor material layer, and a second insulating material layer successively on the insulating substrate to cover the gate electrode, forming a resist pattern on a surface of the second insulating material layer, etching the second insulating material layer, the semiconductor material layer, and the first insulating material layer using the resist pattern as a mask, thereby forming a semiconductor layer of the semiconductor material layer having a predetermined shape, a gate insulating film of the first insulating material layer having the same shape as that of the semiconductor layer, and an interlayer insulating film of the second insulating material layer with an end portion of the semiconductor layer being exposed from the interlayer insulating film, and forming an electrode layer covering a portion of the interlayer insulating film and a portion of the semiconductor layer with the electrode layer being connected to an end portion of the semiconductor layer.

A liquid crystal display device according to the present invention includes an element substrate on which a plurality of semiconductor elements are formed, a counter substrate facing the element substrate, and a liquid crystal layer provided between the counter substrate and the element substrate. The element substrate includes a gate electrode formed on an insulating substrate, a gate insulating film covering the gate electrode, a first semiconductor layer formed on a surface of the gate insulating film and having a channel region facing the gate electrode, and an electrode layer connected to the first semiconductor layer. An island-shaped first interlayer insulating film covering the channel region is formed on a surface of the first semiconductor layer. An end portion of the first interlayer insulating film is interposed between the first semiconductor layer and the electrode layer. Outer edges of the first interlayer insulating film are located further inside than respective corresponding outer edges of the first semiconductor layer by the same width, as viewed in a normal direction of a surface of the insulating substrate. The electrode layer is connected to an end portion of the first semiconductor layer.

### Advantages of the Invention

According to the present invention, the electrode layer is connected to an end portion of the semiconductor layer. Therefore, the width in the predetermined surface direction of the semiconductor layer is reduced, whereby the size of the semiconductor device can be reduced. Moreover, the channel region of the semiconductor layer is covered by the interlayer insulating film. Therefore, when the electrode portion is formed, the channel region can be protected by the interlayer insulating film, whereby a deterioration in characteristics of the semiconductor device can be reduced or prevented.

Also, a high-concentration impurity region is formed in the semiconductor material layer and is crystallized by irradiation with laser light, and thereafter, the channel region of the semiconductor material layer is covered by the second insulating material layer, and the second insulating material layer, the semiconductor material layer, and the first insulating material layer are etched to form the semiconductor layer having a predetermined shape. Therefore, it is possible to reduce or prevent a defect in the semiconductor device which occurs, during the etching, due to damage on the gate insulating film which is caused by a pinhole which occurs when the semiconductor material layer is crystallized.

### BRIEF DESCRIPTION OF THE DRAWINGS

FIG. 1 is a plan view showing a configuration of a TFT according to a first embodiment.

FIG. 2 is a cross-sectional view taken along line II-II of FIG. 1.

FIG. 3 is a plan view showing an intersection portion of a gate line and a source line in the first embodiment.

FIG. 4 is a cross-sectional view taken along line IV-IV of FIG. 3.

FIG. 5 is an enlarged plan view schematically showing a portion of a TFT substrate in the first embodiment.

FIG. 6 is a cross-sectional view showing a configuration of a portion of a liquid crystal display device in the first embodiment.

FIG. 7 is a cross-sectional view showing a gate electrode included in the TFT in the first embodiment.

FIG. 8 is a cross-sectional view showing the gate line included in the intersection portion in the first embodiment.

FIG. 9 is a cross-sectional view showing a semiconductor material layer included in the TFT in the first embodiment.

FIG. 10 is a cross-sectional view showing the semiconductor material layer included in the intersection portion in the first embodiment.

FIG. 11 is a cross-sectional view showing the semiconductor material layer into which an impurity element is implanted through a second mask in the first embodiment.

FIG. 12 is a cross-sectional view showing the second mask provided in a region where the intersection portion is to be formed in the first embodiment.

FIG. 13 is a cross-sectional view showing the semiconductor material layer irradiated with laser light in the first embodiment.

FIG. 14 is a cross-sectional view showing the semiconductor material layer in the intersection portion in the first embodiment.

FIG. 15 is a cross-sectional view showing a second insulating material layer included in the TFT in the first embodiment.

FIG. 16 is a cross-sectional view showing the second insulating material layer included in the intersection portion in the first embodiment.

FIG. 17 is a cross-sectional view showing the second insulating material layer which is etched in the first embodiment.

FIG. 18 is a cross-sectional view showing the second insulating material layer which is etched in the first embodiment.

FIG. 19 is a cross-sectional view showing a first semiconductor layer included in the TFT in the first embodiment.

FIG. 20 is a cross-sectional view showing a second semiconductor layer included in the intersection portion in the first embodiment.

FIG. 21 is a cross-sectional view showing a gate insulating film and a first interlayer insulating film included in the TFT in the first embodiment.

FIG. 22 is a cross-sectional view showing the gate insulating film and a second interlayer insulating film included in the intersection portion in the first embodiment.

FIG. 23 is a cross-sectional view showing an electrode material layer included in the TFT in the first embodiment.

FIG. 24 is a cross-sectional view showing the electrode material layer included in the intersection portion in the first embodiment.

FIG. 25 is a cross-sectional view showing drain/source electrodes included in the TFT in the first embodiment.

FIG. 26 is a cross-sectional view showing a source line included in the intersection portion in the first embodiment.

FIG. 27 is a cross-sectional view showing a fourth interlayer insulating film in which a contact hole is formed in the first embodiment.

FIG. 28 is a cross-sectional view showing the fourth interlayer insulating film covering the intersection portion in the first embodiment.

FIG. 29 is a cross-sectional view showing an ITO material layer included in the TFT in the first embodiment.

FIG. 30 is a cross-sectional view showing the ITO material layer formed on the intersection portion in the first embodiment.

FIG. 31 is a cross-sectional view showing a semiconductor material layer into which an impurity element is implanted through a mask, in a region where a TFT according to a second embodiment is to be formed.

FIG. 32 is a cross-sectional view showing the semiconductor material layer into which the impurity element is implanted through the mask, in a region where an intersection portion is to be formed in the second embodiment.

FIG. 33 is a cross-sectional view showing the semiconductor material layer irradiated with laser light in the second embodiment.

FIG. 34 is a cross-sectional view showing the semiconductor material layer included in the intersection portion in the second embodiment.

FIG. 35 is a cross-sectional view showing a second insulating material layer included in the TFT in the second embodiment.

FIG. 36 is a cross-sectional view showing the second insulating material layer included in the intersection portion in the second embodiment.

FIG. 37 is a cross-sectional view showing the second insulating material layer which is etched in the second embodiment.

FIG. 38 is a cross-sectional view showing the second insulating material layer which is etched in the second embodiment.

FIG. 39 is a cross-sectional view showing a second insulating material layer included in a TFT according to a third embodiment.

FIG. 40 is a cross-sectional view showing the second insulating material layer included in an intersection portion in the third embodiment.

FIG. 41 is a cross-sectional view showing the second insulating material layer which is etched in the third embodiment.

FIG. 42 is a cross-sectional view showing the second insulating material layer which is etched in the third embodiment.

FIG. 43 is a cross-sectional view showing a configuration of a conventional TFT.

FIG. 44 is a plan view showing a region where a source line and a gate line intersect in the conventional art.

FIG. 45 is a cross-sectional view taken along line XXXXV-XXXXV of FIG. 44.

### DESCRIPTION OF EMBODIMENTS

Embodiments of the present invention will be described in detail hereinafter with reference to the accompanying drawings. Note that the present invention is not intended to be limited to the embodiments described below.

### First Embodiment of the Invention

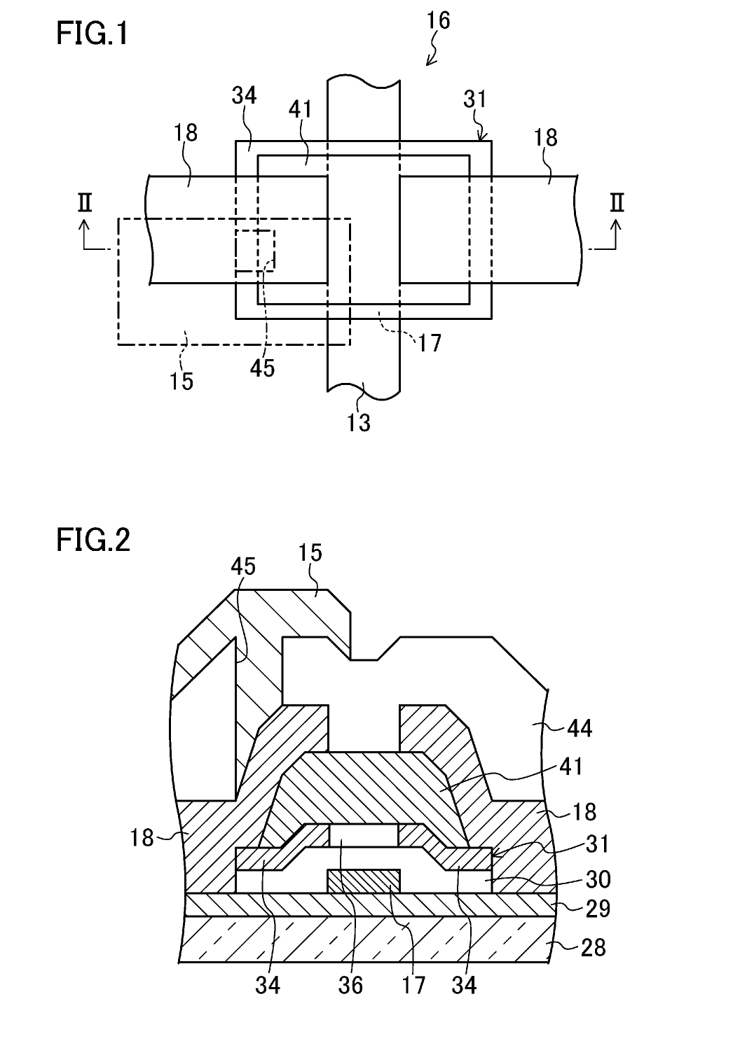

FIGS. 1-30 show a first embodiment of the present invention.

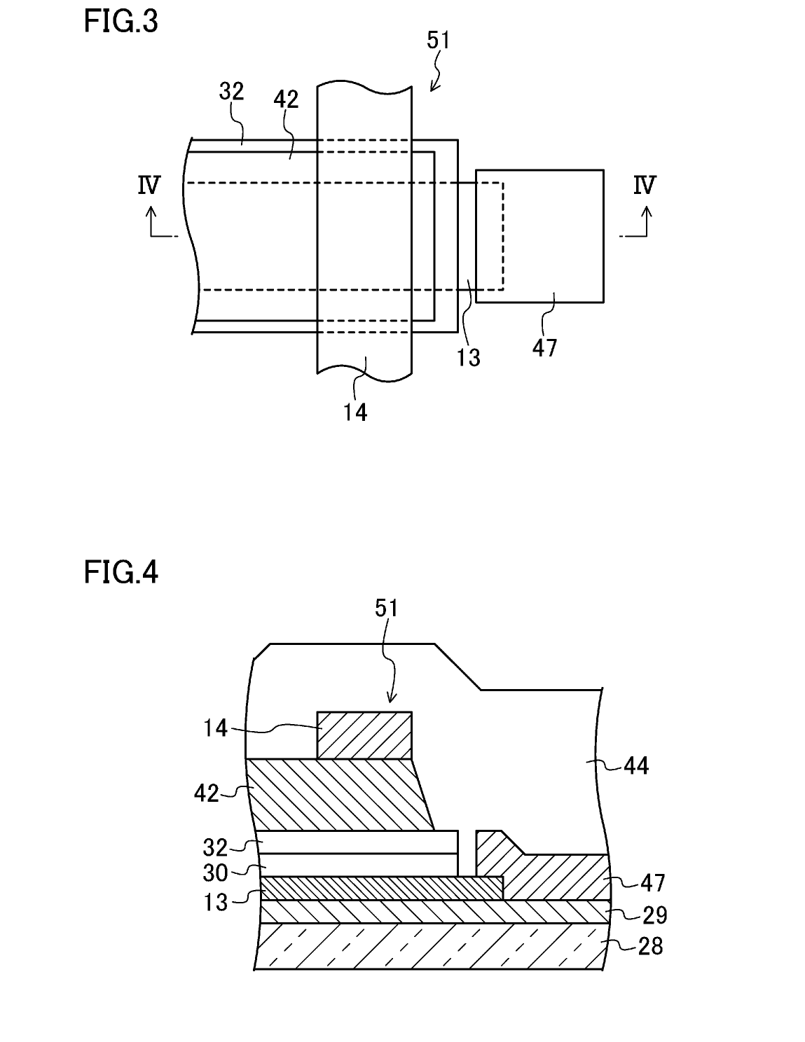

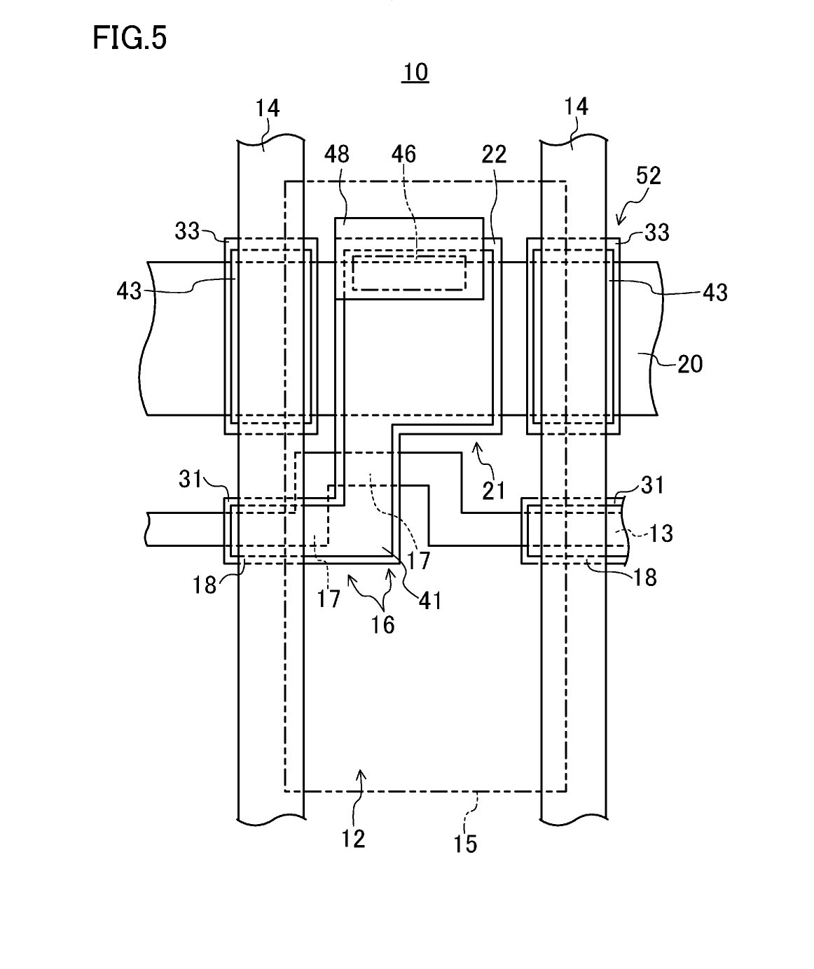

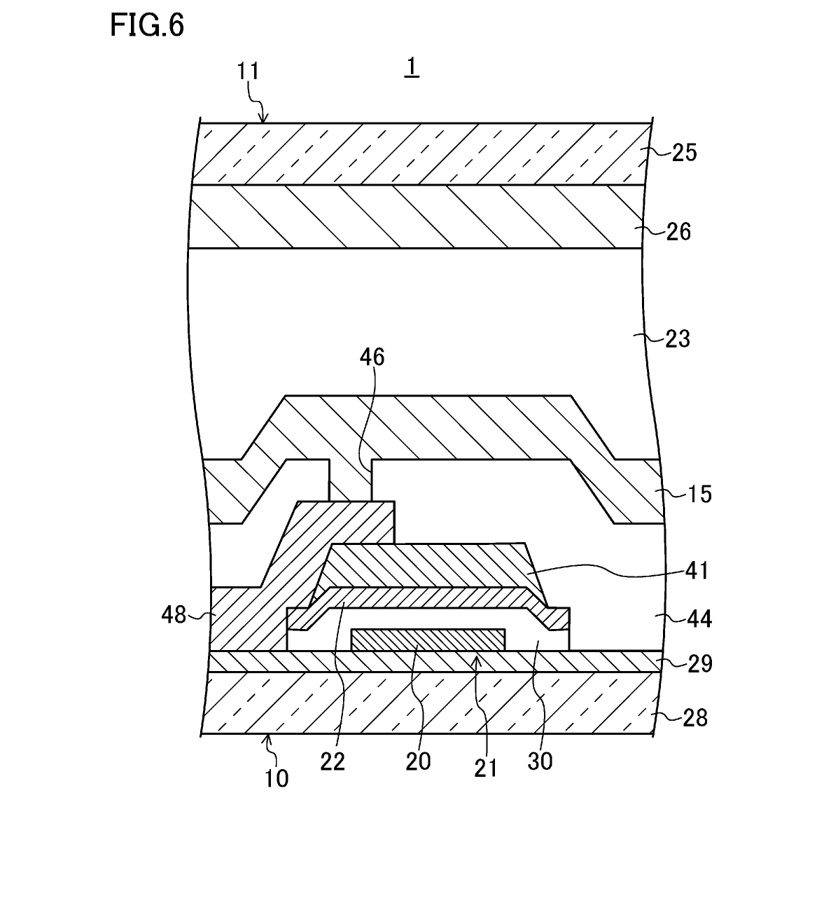

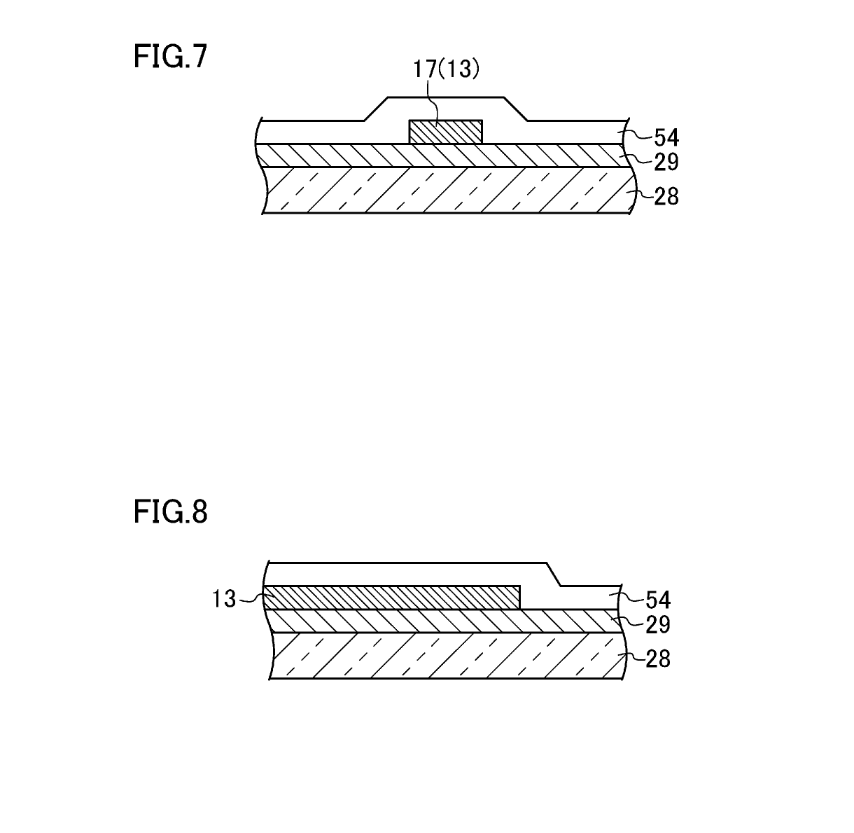

FIG. 1 is a plan view showing a configuration of a thin film transistor (TFT) 16. FIG. 2 is a cross-sectional view taken along line II-II of FIG. 1. FIG. 3 is a plan view showing an intersection portion of a gate line 13 and a source line 14. FIG. 4 is a cross-sectional view taken along line IV-IV of FIG. 3. FIG. 5 is an enlarged plan view schematically showing a portion of a TFT substrate 10. FIG. 6 is a cross-sectional view showing a configuration of a portion of a liquid crystal display device 1. FIGS. 7-30 are cross-sectional views showing a process of manufacturing the TFT 16 or the intersection portion.

In this embodiment, the liquid crystal display device 1 including a plurality of the TFTs 16 (semiconductor elements) will be described as an example.

As shown in FIG. 6, the liquid crystal display device 1 includes the TFT substrate 10 (element substrate), a counter substrate 11 facing the TFT substrate 10, and a liquid crystal layer 23 provided between the counter substrate 11 and the TFT substrate 10.

The counter substrate 11 includes a glass substrate 25 (transparent insulating substrate), and a common electrode 26 formed on a side facing the liquid crystal layer 23 of the glass substrate 25. The common electrode 26 includes a transparent conductive film of, for example, indium tin oxide (ITO).

On the other hand, the TFT substrate 10 is a so-called active matrix substrate. The TFT substrate 10 includes a plurality of pixels 12 arranged in a matrix, each of which is a unit region of a display. As shown in FIG. 5, a pixel electrode 15 for driving the liquid crystal layer is formed for each pixel 12. The pixel electrode 15 has a rectangular shape and is formed of a transparent conductive film of, for example, ITO.

The TFT substrate 10 includes a glass substrate 28 (transparent insulating substrate), a plurality of the gate lines 13 formed on the glass substrate 28, and a plurality of the source lines 14 intersecting the gate lines 13. As shown in FIG. 5, the source lines 14 extend in parallel to each other. The gate lines 13 are spaced from each other by a predetermined spacing and intersect the source lines 14.

Holding capacitor elements 21 each including a capacitor line 20 intersecting the source lines 14 and a capacitor electrode 22 facing the capacitor line 20 are also formed on the glass substrate 28. The capacitor electrode 22 is formed of a semiconductor layer of, for example, polysilicon doped with a high concentration of an impurity element.

The TFT 16 which is a switching element which switches and drives the pixel electrode 15 is formed on the glass substrate 28 for each pixel 12. The TFT 16 of this embodiment is of dual gate type and, for example, includes two gate electrodes 17. As a result, the leakage current is reduced, and in addition, the reliability against a high applied voltage is improved.

(Configuration of TFT 16)

As shown in FIGS. 1 and 2, the TFT 16 has a bottom gate configuration which is called “inverted staggered.” A protection film 29 is uniformly formed on a surface of the glass substrate 28 included in the TFT substrate 10. On the glass substrate 28, the gate electrode 17 which is formed as a portion of the gate line 13 on a surface of the protection film 29, a gate insulating film 30 which covers the gate electrode 17, a first semiconductor layer 31 which is formed on a surface of the gate insulating film 30, and drain/source electrodes 18 of an electrode layer connected to the first semiconductor layer 31, are formed.

As shown in FIG. 2, the gate insulating film 30 is formed of, for example, a silicon nitride film or a silicon oxide film, and has an island shape having a width greater than that of the gate electrode 17. The first semiconductor layer 31 is formed of, for example, polysilicon, and has the same island shape as that of the gate insulating film 30. In other words, side surfaces of the gate insulating film 30 and the first semiconductor layer 31 are on the same plane.

The first semiconductor layer 31 has a channel region 36 facing the gate electrode 17 and drain/source regions 34 between which the channel region 36 is interposed. The drain/source regions 34 are doped with a high concentration of an impurity element. The drain/source region 34 which overlaps the source line 14 is electrically connected to the source line 14.

An island-shaped first interlayer insulating film 41 covering the channel region 36 is formed on a surface of the first semiconductor layer 31. Outer edges (or an outline) of the first interlayer insulating film 41 are located further inside than outer edges (or an outline) of the first semiconductor layer 31. Specifically, as viewed in the normal direction of the top surface of the glass substrate 28, the outer edges of the first interlayer insulating film 41 are located further inside than the respective corresponding outer edges of the first semiconductor layer 31 by the same width (e.g., about 0.1-2.0 μm).

As shown in FIG. 2, a width of the first interlayer insulating film 41 in a predetermined surface direction along the surface of the glass substrate 28 is greater than a width in the predetermined surface direction of the gate electrode 17. The width in the predetermined surface direction of the first interlayer insulating film 41 is also greater than that of the channel region 36. On the other hand, the width in the predetermined surface direction of the first interlayer insulating film 41 is smaller than that of the first semiconductor layer 31.

The drain/source electrodes 18 are formed on the protection film 29, covering the first interlayer insulating film 41. End portions of the first interlayer insulating film 41 are sandwiched between the first semiconductor layer 31 and the drain/source electrodes 18. Thus, the drain/source electrodes 18 are connected to end portions of the first semiconductor layer 31. The side surfaces of the gate insulating film 30 and the first semiconductor layer 31 are covered directly by the drain/source electrodes 18.

The drain/source electrodes 18 are covered by a fourth interlayer insulating film 44. The fourth interlayer insulating film 44 has a contact hole 45 penetrating therethrough on one of the drain/source electrodes 18. The pixel electrode 15 of an ITO electrode layer is formed on a surface of the fourth interlayer insulating film 44. The pixel electrode 15 is connected via the contact hole 45 to one of the drain/source electrodes 18.

(Configuration of Holding Capacitor Element 21)

As shown in FIGS. 5 and 6, the capacitor line 20 included in the holding capacitor element 21 is formed of the same material as that of the gate line 13, and is formed on a surface of the protection film 29. The capacitor line 20 is covered by the island-shaped gate insulating film 30. The capacitor electrode 22 having the same shape as that of the gate insulating film 30 is formed on a surface of the gate insulating film 30.

The first interlayer insulating film 41 is formed on a surface of the capacitor electrode 22. The first interlayer insulating film 41 on the capacitor electrode 22 has a width in the predetermined surface direction smaller than that of the capacitor electrode 22. As shown in FIGS. 5 and 6, an island-shaped electrode portion 48 is formed on the protection film 29, covering a portion of the first interlayer insulating film 41.

As shown in FIG. 6, the electrode portion 48 is provided to surround an end portion of the first interlayer insulating film 41, and is connected to an end portion of the capacitor electrode 22. The capacitor electrode 22 and the first interlayer insulating film 41 are covered by the fourth interlayer insulating film 44. The fourth interlayer insulating film 44 has a contact hole 46 penetrating therethrough on the electrode portion 48. The pixel electrode 15 is formed on a surface of the fourth interlayer insulating film 44. The pixel electrode 15 is connected via the contact hole 46 to the electrode portion 48.

(Configuration of Intersection Portion 51)

As shown in FIGS. 3 and 4, an intersection portion 51 at which the gate line 13 and the source line 14 intersect is formed at an end portion of the gate line 13. A second semiconductor layer 32, and a second interlayer insulating film 42 which is formed on a surface of the second semiconductor layer 32 and is formed of the same material as that of the first interlayer insulating film 41, are interposed between the gate line 13 and the source line 14 which intersect each other.

Specifically, as shown in FIG. 4, the protection film 29 is formed on a surface of the glass substrate 28. The gate line 13, and an electrode terminal 47 connected to the gate line 13, are formed on a surface of the protection film 29. The electrode terminal 47 is formed of the same material as that of the drain/source electrodes 18. A portion of the electrode terminal 47 overlaps an end portion of the gate line 13.

The gate line 13 is covered by the gate insulating film 30. The second semiconductor layer 32 and the second interlayer insulating film 42 are successively formed and stacked on a surface of the gate insulating film 30. The source line 14 is formed on a surface of the second interlayer insulating film 42. The source line 14, the second interlayer insulating film 42, and the electrode terminal 47 are covered by the fourth interlayer insulating film 44.

(Configuration of Intersection Portion 52)

As shown in FIG. 5, an intersection portion 52 is formed at an intersection portion of the capacitor line 20 and the source line 14. At the intersection portion 52, a third semiconductor layer 33 and a third interlayer insulating film 43 formed on a surface of the third semiconductor layer 33 are interposed between the capacitor line 20 and the source line 14. The third semiconductor layer 33 is formed of the same material as that of the second semiconductor layer 32. The third interlayer insulating film 43 is formed of the same material as that of the first interlayer insulating film 41 and the second interlayer insulating film 42.

—Manufacturing Method—

Next, methods for manufacturing the TFT substrate 10 and the liquid crystal display device 1 including the TFT substrate 10 will be described.

Initially, the gate electrode 17 having a predetermined shape is formed on the glass substrate 28. Here, FIG. 7 is a cross-sectional view showing the gate electrode 17 included in the TFT 16. FIG. 8 is a cross-sectional view showing the gate line 13 included in the intersection portion 51.

Specifically, as shown in FIGS. 7 and 8, the protection film 29 is uniformly formed on a surface of the glass substrate 28. The protection film 29 is preferably formed of a material having a high etch selectivity ratio with respect to a first insulating material layer 54 which is to form the gate insulating film 30 described below. Next, a metal material layer is uniformly formed on a surface of the protection film 29, and photolithography is performed using a first mask (not shown), whereby the gate line 13 including the gate electrode 17, and the capacitor line 20, are formed of the metal material layer.

Next, the first insulating material layer 54, a semiconductor material layer 55, and a second insulating material layer 56 are successively formed and stacked, for example, by CVD, on the glass substrate 28, covering the gate electrode 17 (the gate line 13) and the capacitor line 20.

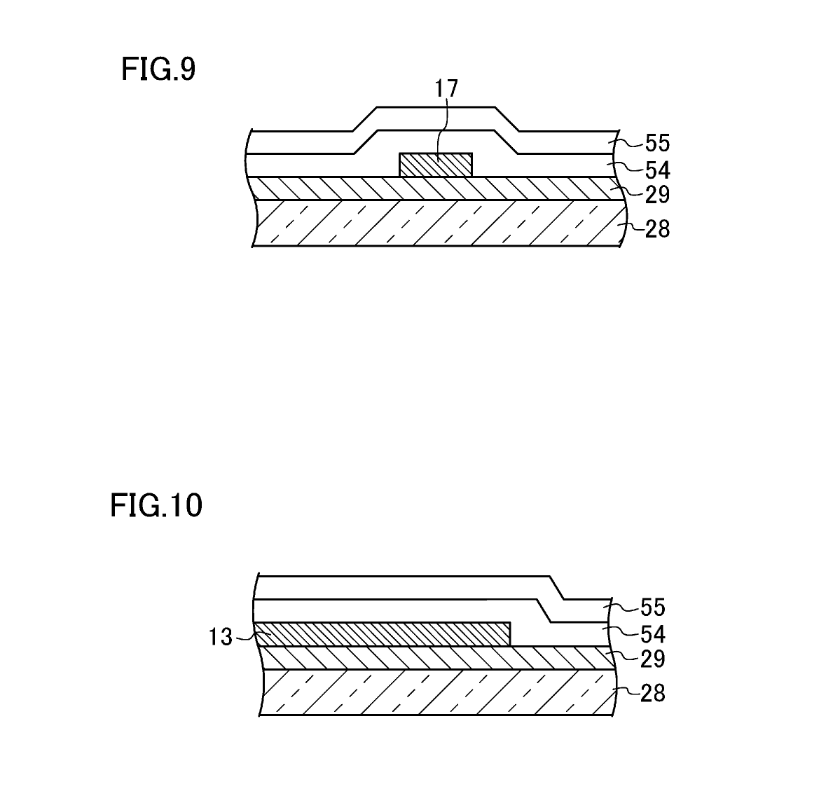

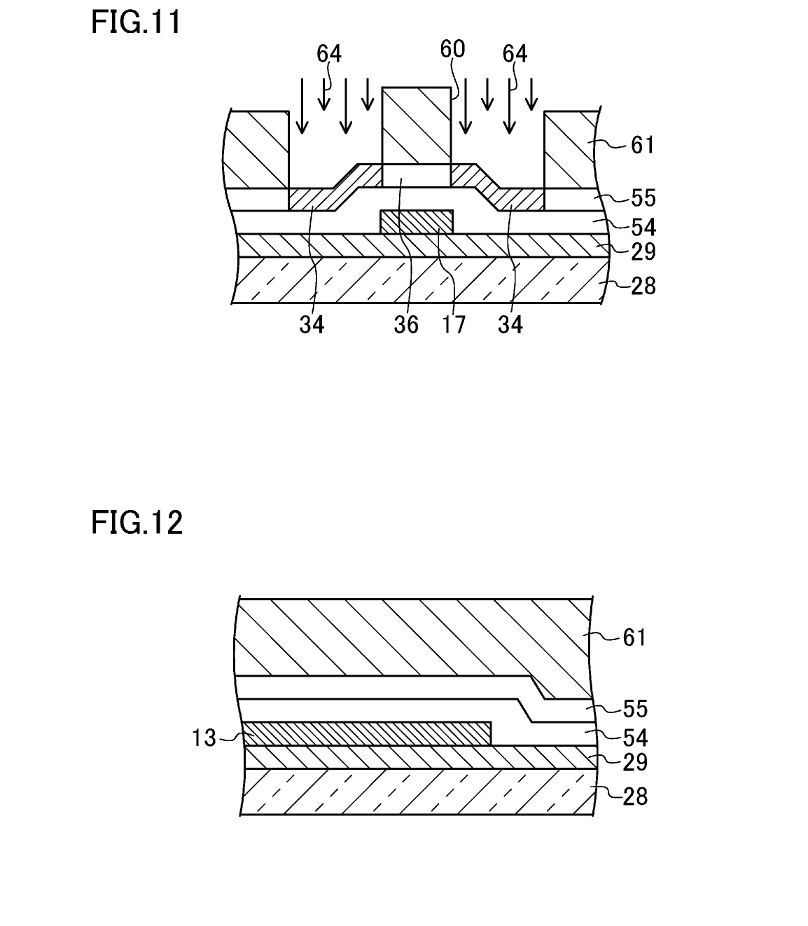

Here, FIG. 9 is a cross-sectional view showing the semiconductor material layer 55 included in the TFT 16. FIG. 10 is a cross-sectional view showing the semiconductor material layer 55 included in the intersection portion 51. FIG. 11 is a cross-sectional view showing the semiconductor material layer 55 into which an impurity element 64 is implanted through a second mask 61. FIG. 12 is a cross-sectional view showing the second mask 61 provided in a region where the intersection portion 51 is to be formed.

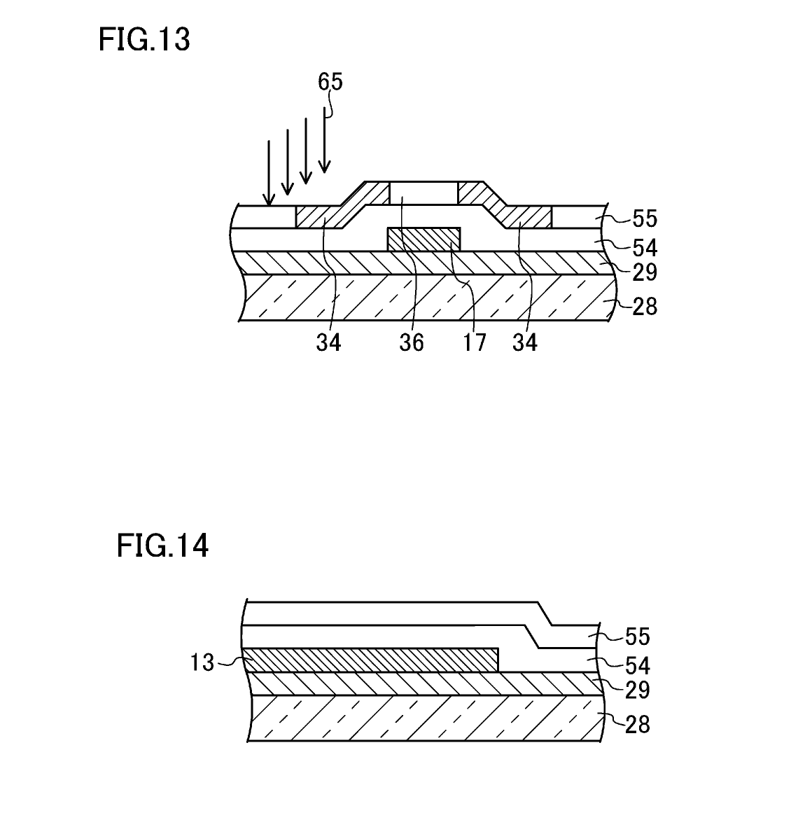

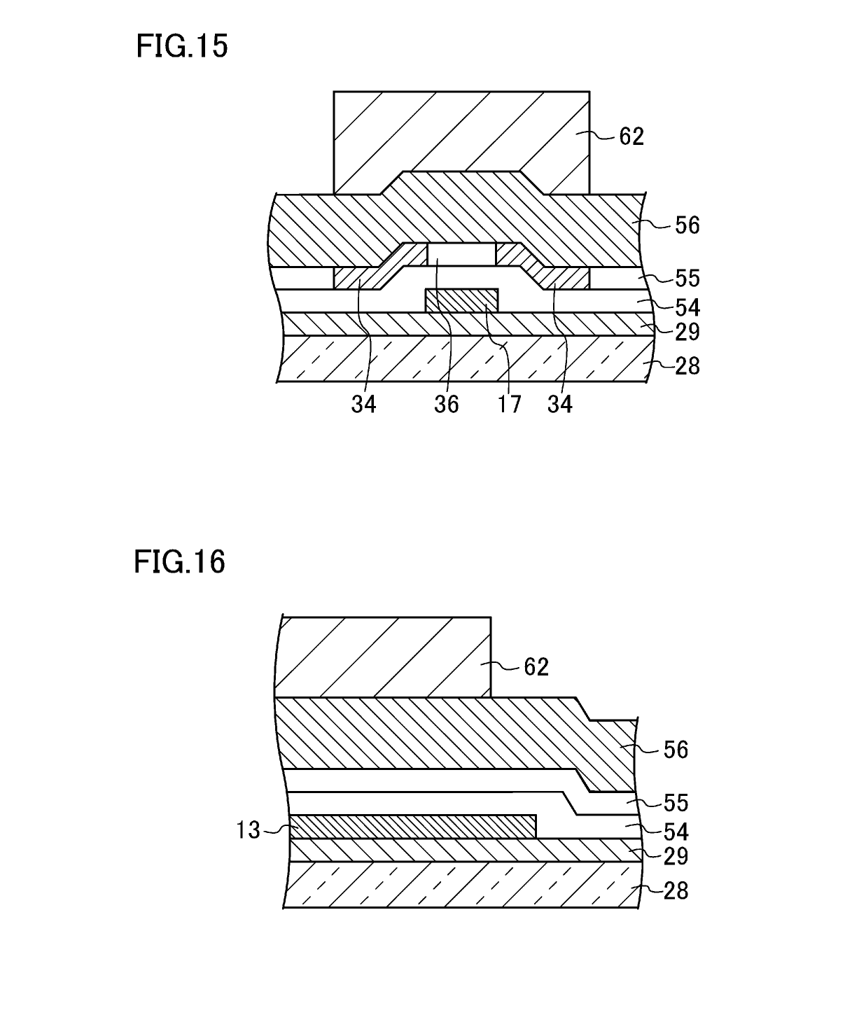

FIG. 13 is a cross-sectional view showing the semiconductor material layer 55 irradiated with laser light 65. FIG. 14 is a cross-sectional view showing the semiconductor material layer 55 included in the intersection portion 51. FIG. 15 is a cross-sectional view showing the second insulating material layer included in the TFT 16. FIG. 16 is a cross-sectional view showing the second insulating material layer included in the intersection portion 51.

Specifically, as shown in FIGS. 9 and 10, the semiconductor material layer 55 of silicon is uniformly formed on a surface of the gate insulating film 30. Next, as shown in FIGS. 11 and 12, the second mask 61 is formed on a surface of the semiconductor material layer 55. The second mask 61 is formed as a resist pattern in a region where the TFT 16 is to be formed. The second mask 61 covers a region which is to be the channel region 36, and has openings 60 on regions which are to be the drain/source regions 34. As shown in FIG. 12, entire regions which are to be the intersection portions 51 and 52 are covered by the second mask 61. The second mask 61 also has an opening (not shown) on a region where the capacitor electrode 22 is to be formed.

Thereafter, ions of the impurity element 64 are implanted into the semiconductor material layer 55 through the second mask 61. As a result, the drain/source regions 34 and the capacitor electrode 22 which are high-concentration impurity regions are formed in the semiconductor material layer 55 at predetermined positions. A region interposed between the drain/source regions 34 is the channel region 36. On the other hand, as shown in FIG. 14, a high-concentration impurity region is not formed in regions which are to be the intersection portions 51 and 52.

Note that when an N-type or P-type CMOS is formed, two types of impurity ions are implanted, and therefore, photolithograpy is performed twice.

Thereafter, as shown in FIGS. 13 and 14, after the second mask 61 is removed, the entire semiconductor material layer 55 is irradiated with laser light, such as excimer laser etc., resulting in polycrystallization of the semiconductor material layer 55. By the thermal treatment with laser light, the high-concentration impurity regions (the drain/source regions 34) can be thermally activated simultaneously with the polycrystallization of the semiconductor material layer 55. In other words, in this embodiment, a thermal treatment step of only activating the high-concentration impurity regions can be removed.

Note that if the polycrystallization step is not performed, a step of activating the high-concentration impurity regions may be subsequently performed.

Next, as shown in FIGS. 15 and 16, the second insulating material layer 56 is uniformly formed on a surface of the semiconductor material layer 55 by CVD etc. The second insulating material layer 56 is preferably formed of a material having a high etch selectivity ratio with respect to silicon of the semiconductor material layer 55.

Next, a third mask 62 is formed on a surface of the second insulating material layer 56. The third mask 62 is formed as a resist pattern which has the same shape as that of the first semiconductor layer 31, the second semiconductor layer 32, and the third semiconductor layer 33 as viewed in the normal direction of the top surface of the glass substrate 28, and overlaps the semiconductor layers 31-33.

Thereafter, the semiconductor material layer 55, the first insulating material layer 54, and the second insulating material layer 56 are etched through the third mask 62.

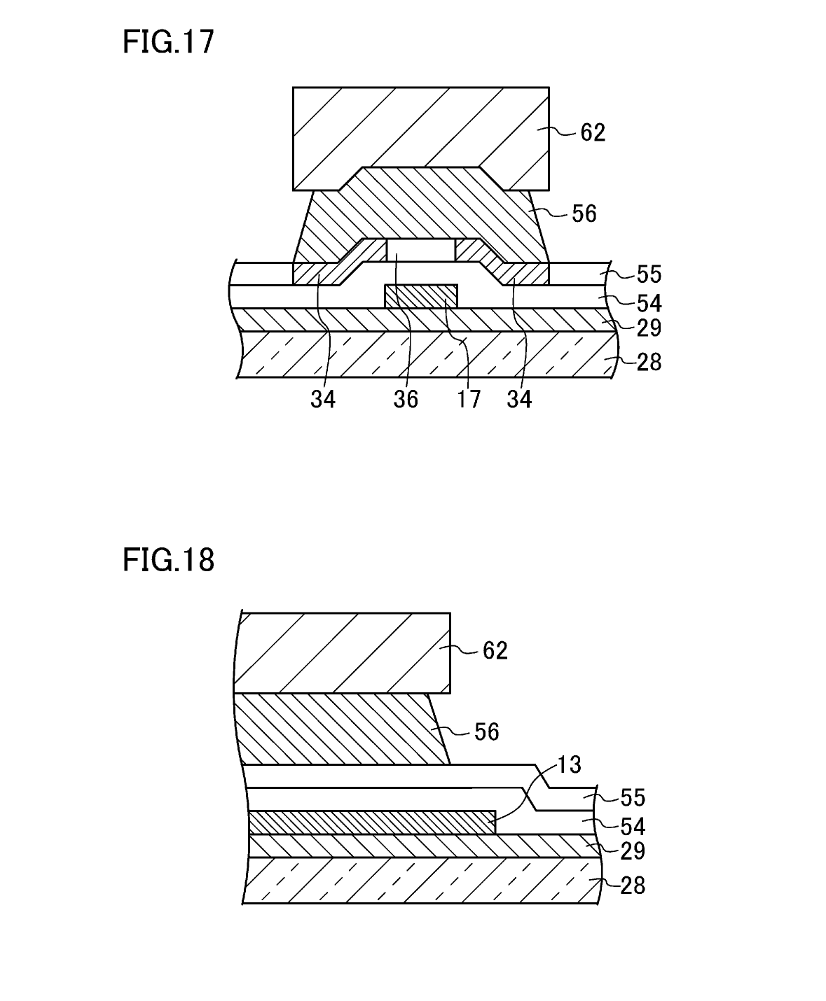

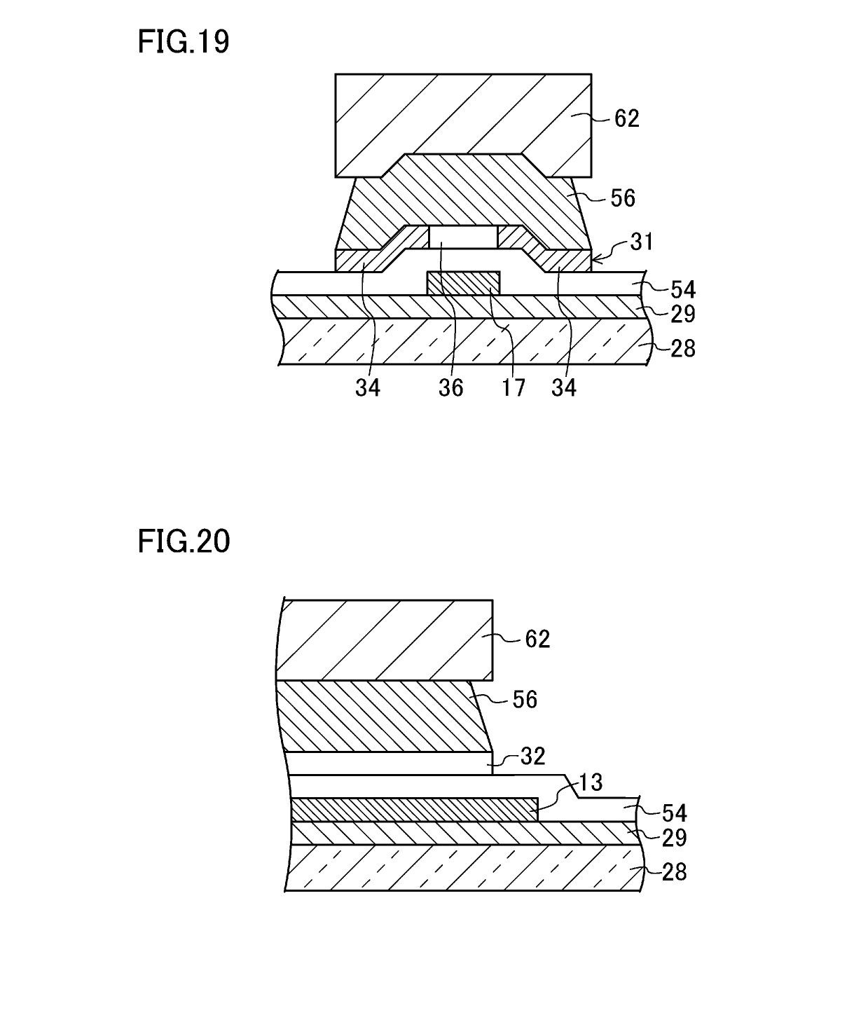

Here, FIG. 17 is a cross-sectional view showing the etched second insulating material layer 56. FIG. 18 is a cross-sectional view showing the etched second insulating material layer 56. FIG. 19 is a cross-sectional view showing the first semiconductor layer 31 included in the TFT 16. FIG. 20 is a cross-sectional view showing the second semiconductor layer 32 included in the intersection portion 51.

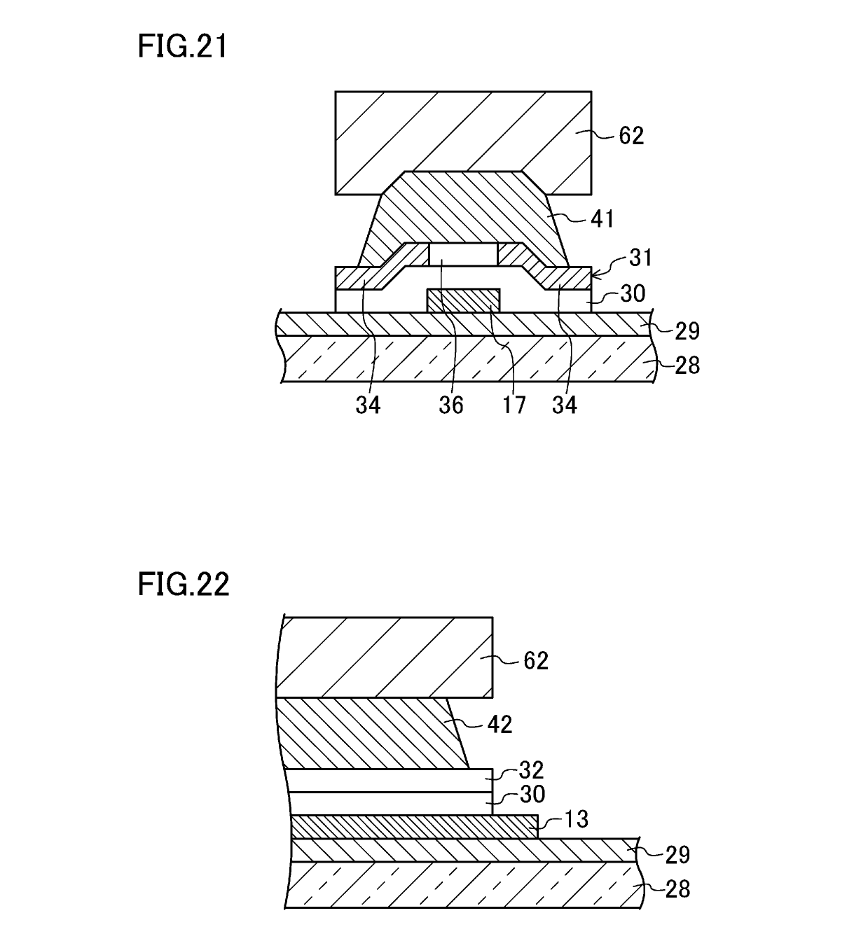

FIG. 21 is a cross-sectional view showing the gate insulating film 30 and the first interlayer insulating film 41 included in the TFT 16. FIG. 22 is a cross-sectional view showing the gate insulating film 30 and the second interlayer insulating film 42 included in the intersection portion 51.

Specifically, as shown in FIGS. 17 and 18, initially, the second insulating material layer 56 is etched through the third mask 62. This etching needs to be isotropic etching, and therefore, is preferably performed by wet etching. A lower end portion of the etched second insulating material layer 56 has the same width as that of the third mask 62, and has the same width as that of each of the first semiconductor layer 31, the second semiconductor layer 32, and the third semiconductor layer 33.

Next, as shown in FIGS. 19 and 20, the semiconductor material layer 55 is etched in an anisotropic manner through the third mask 62 to form the first semiconductor layer 31, the second semiconductor layer 32, and the third semiconductor layer 33 of the semiconductor material layer 55 which have a predetermined shape. Next, the first insulating material layer 54 is etched in an anisotropic manner through the third mask 62 to form the gate insulating film 30 of the first insulating material layer 54 which has the same shape as that of the first semiconductor layer 31, the second semiconductor layer 32, and the third semiconductor layer 33. In this case, as shown in FIGS. 21 and 22, the second insulating material layer 56 is simultaneously etched sideways, so that the first interlayer insulating film 41, the second interlayer insulating film 42, and the third interlayer insulating film 43 are formed of the second insulating material layer 56.

The first interlayer insulating film 41, the second interlayer insulating film 42, and the third interlayer insulating film 43 each have sloped side surfaces. In a region where the TFT 16 and the holding capacitor element 21 are to be formed, an end portion of the first semiconductor layer 31 is exposed from the first interlayer insulating film 41. In a region where the intersection portion 51 is to be formed, an end portion of the second semiconductor layer 32 is exposed from the second interlayer insulating film 42. In a region where the intersection portion 52 is to be formed, an end portion of the third semiconductor layer 33 is exposed from the third interlayer insulating film 43. The degree of exposure of the end portion of each of the semiconductor layers 31-33 is controlled by the amount of etching. In order to protect the glass substrate 28, the protection film 29 preferably has a sufficiently high selectivity ratio with respect to the gate insulating film 30 etc.

Next, the drain/source electrodes 18, the source line 14, the electrode terminal 47, and the electrode portion 48 are formed.

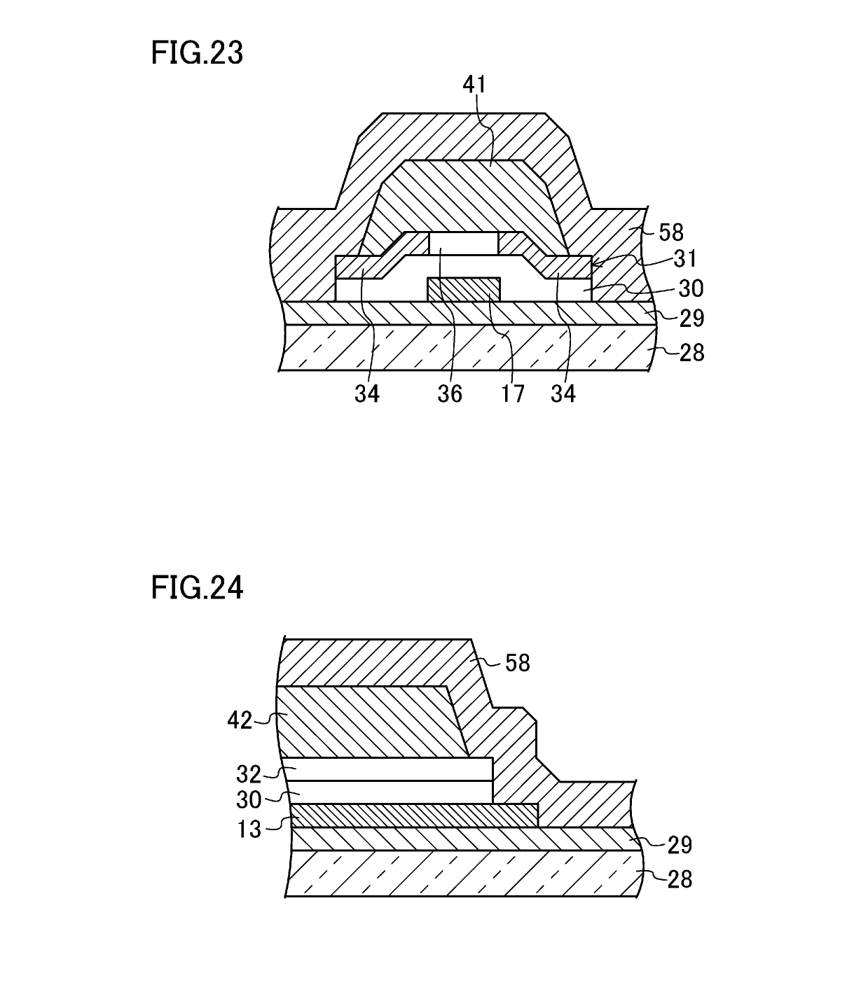

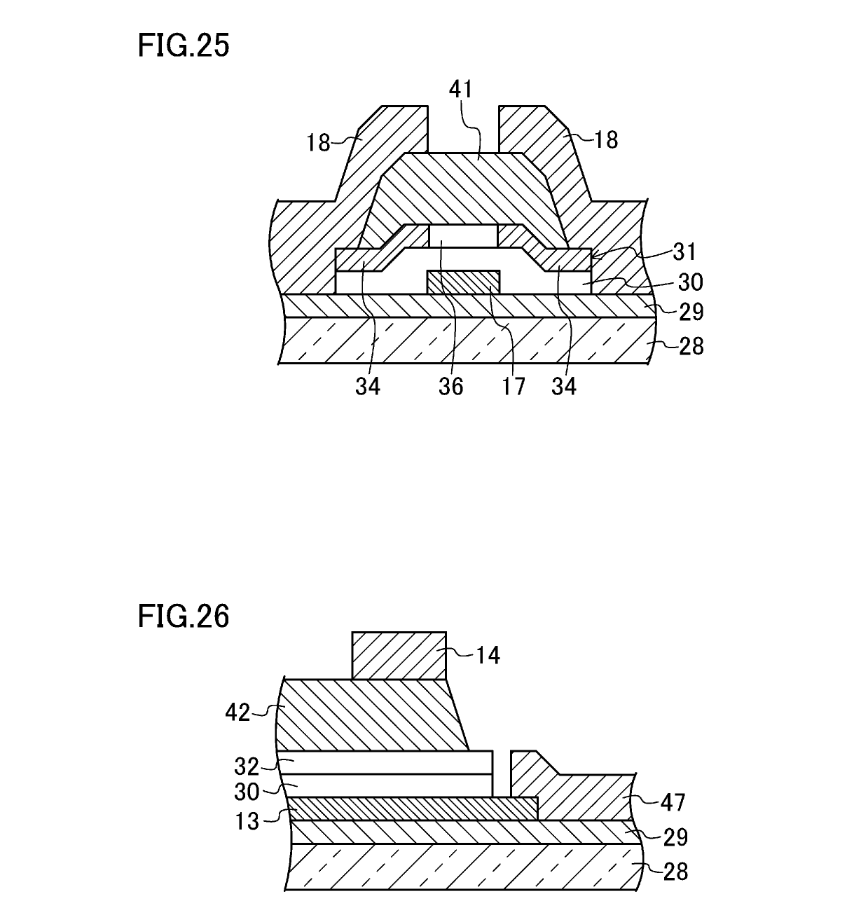

Here, FIG. 23 is a cross-sectional view showing an electrode material layer 58 included in the TFT 16. FIG. 24 is a cross-sectional view showing the electrode material layer 58 included in the intersection portion 51. FIG. 25 is a cross-sectional view showing drain/source electrodes included in the TFT 16. FIG. 26 is a cross-sectional view showing the source line 14 included in the intersection portion 51.

Specifically, as shown in FIGS. 23 and 24, the electrode material layer 58 of a metal material is uniformly formed to cover the first interlayer insulating film 41, the second interlayer insulating film 42, and the third interlayer insulating film 43. Next, as shown in FIGS. 25 and 26, the electrode material layer 58 is etched through a fourth mask (not shown) to form the drain/source electrodes 18 which cover a portion of the first interlayer insulating film 41 and a portion (end portions) of the first semiconductor layer 31. Thus, the drain/source electrodes 18 are connected to the end portions of the first semiconductor layer 31.

The electrode portion 48 is formed to cover a portion of the first interlayer insulating film 41 and end portions of the capacitor electrode 22, so that the electrode portion 48 is connected to the capacitor electrode 22. The source line 14 which covers a portion of the second interlayer insulating film 42 and a portion of the third interlayer insulating film 43, and the electrode terminal 47 which covers an end portion of the gate line 13, are formed As a result, the electrode terminal 47 is connected to the gate line 13. The source line 14 and the capacitor line 20 are insulated from each other by the third semiconductor layer 33 and the third interlayer insulating film 43. On the other hand, the source line 14 and the gate line 13 are insulated from each other by the second semiconductor layer 32 and the second interlayer insulating film 42.

Next, the fourth interlayer insulating film 44 and the pixel electrode 15 are formed.

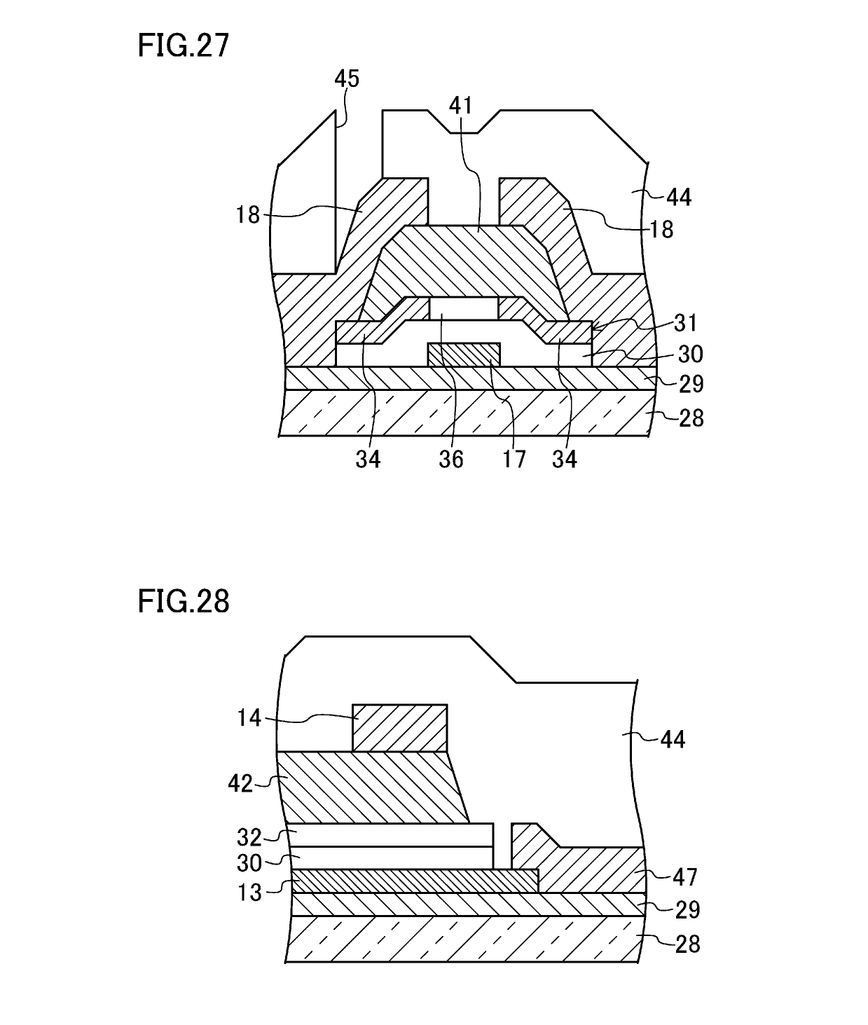

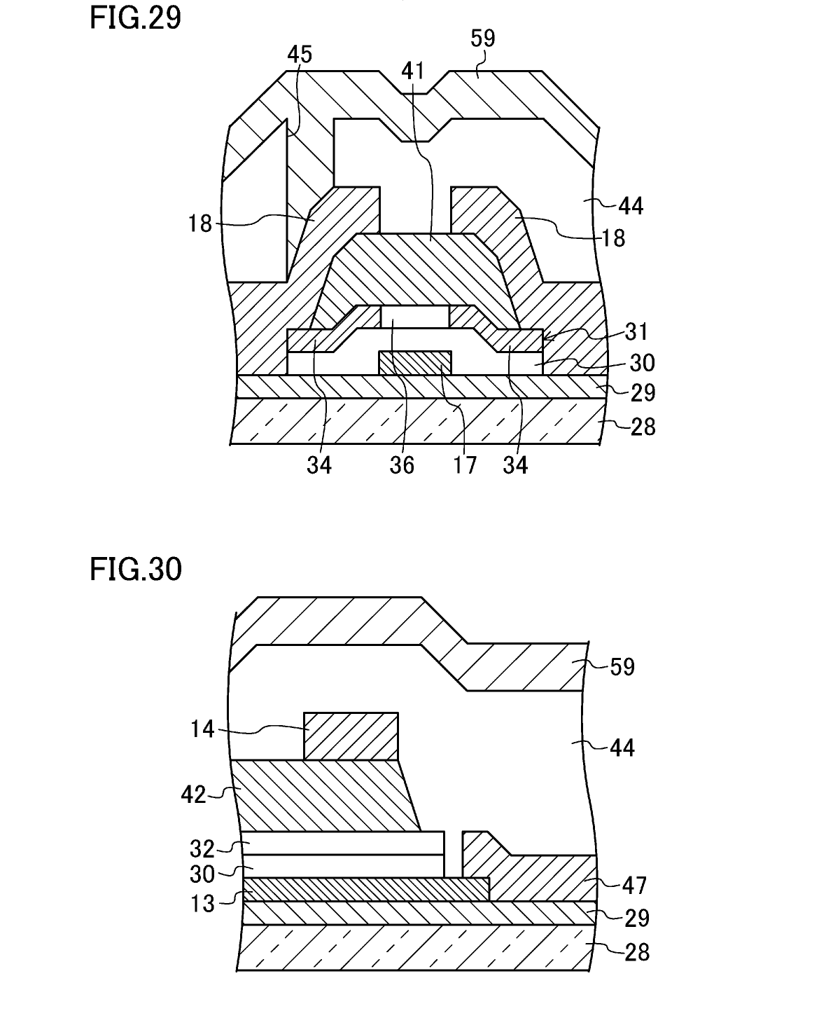

Here, FIG. 27 is a cross-sectional view showing the fourth interlayer insulating film 44 in which the contact hole 45 is formed. FIG. 28 is a cross-sectional view showing the fourth interlayer insulating film 44 covering the intersection portion 51. FIG. 29 is a cross-sectional view showing an ITO material layer 59 included in the TFT 16. FIG. 30 is a cross-sectional view showing the ITO material layer 59 formed on the intersection portion 51.

Specifically, as shown in FIGS. 27 and 28, the fourth interlayer insulating film 44 is uniformly formed to cover the drain/source electrodes 18, the source line 14, the electrode terminal 47, and the electrode portion 48. Next, the contact hole 45 is formed in the fourth interlayer insulating film 44 on one of the drain/source electrodes 18 by photolithography (the contact hole 45 penetrates through the fourth interlayer insulating film 44). Thereafter, as shown in FIGS. 29 and 30, the ITO material layer 59 is uniformly formed on a surface of the fourth interlayer insulating film 44. In this case, the ITO material layer 59 is formed inside the contact hole 45. Next, as shown in FIGS. 2 and 4, the pixel electrode 15 is formed from the ITO material layer 59 by photolithography.

Thus, the TFT substrate 10 is manufactured. The counter substrate 11 is manufactured by forming, on the glass substrate 25, the common electrode 26 of an ITO film, a color filter (not shown), etc. Thereafter, the TFT substrate 10 and the counter substrate 11 are bonded together with the liquid crystal layer 23 and a sealing member (not shown) being interposed therebetween, thereby manufacturing the liquid crystal display device 1.

### Advantages of First Embodiment

Therefore, according to the first embodiment, as shown in FIG. 2, the drain/source electrodes 18 are connected to end portions of the first semiconductor layer 31. Therefore, it is not necessary to provide an extra semiconductor layer in a region further away from the channel region 36 than the region where the drain/source electrode 18 and the first semiconductor layer 31 are connected together. Therefore, a width of the first semiconductor layer 31 in a predetermined surface direction along the surface of the glass substrate 28 is reduced, whereby the size of the TFT 16 can be reduced. In the liquid crystal display device 1, the aperture ratio of each pixel 12 can be improved.

In addition, the channel region 36 of the first semiconductor layer 31 is covered by the first interlayer insulating film 41. Therefore, when the drain/source electrodes 18 are formed, the channel region 36 can be protected by the first interlayer insulating film 41. As a result, a deterioration in characteristics of the TFT 16 can be reduced or prevented.

In the intersection portions 51 and 52, not only the gate insulating film 30 but also the second interlayer insulating film 42 or the third interlayer insulating film 43 are interposed between the source line 14 and the gate line 13 and between the source line 14 and the capacitor line 20. Therefore, the capacitance between the source line 14 and the gate line 13 and the capacitance between the source line 14 and the capacitor line 20 can be reduced. As a result, an increase in signal delay and power consumption can be reduced.

The drain/source electrodes 18 of a metal material is connected, instead of an ITO electrode layer, to the drain/source regions 34 (high-concentration impurity regions), whereby the contact resistance between the first semiconductor layer 31 and the electrode layer can be reduced.

For the TFT 16 including the first semiconductor layer 31 of polysilicon, thermal activation of the high-concentration impurity region can be performed simultaneously with polycrystallization with laser light, whereby the number of steps can be reduced.

### Second Embodiment of the Invention

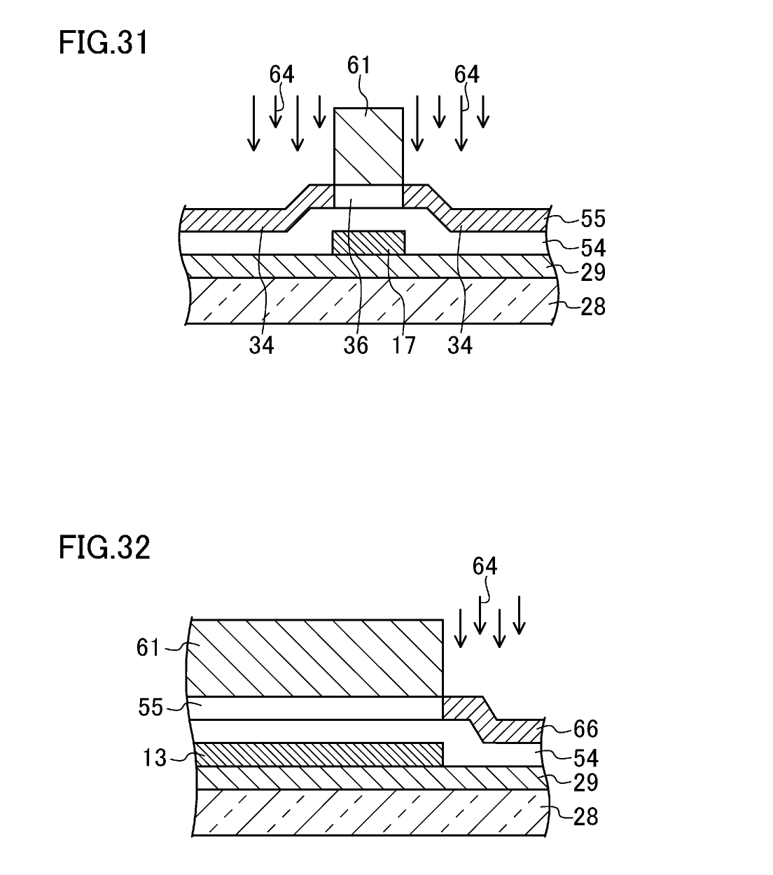

FIGS. 31-38 show a second embodiment of the present invention. Note that, in the following embodiments, the same parts as those of FIGS. 1-30 are indicated by the same reference characters and will not be described in detail.

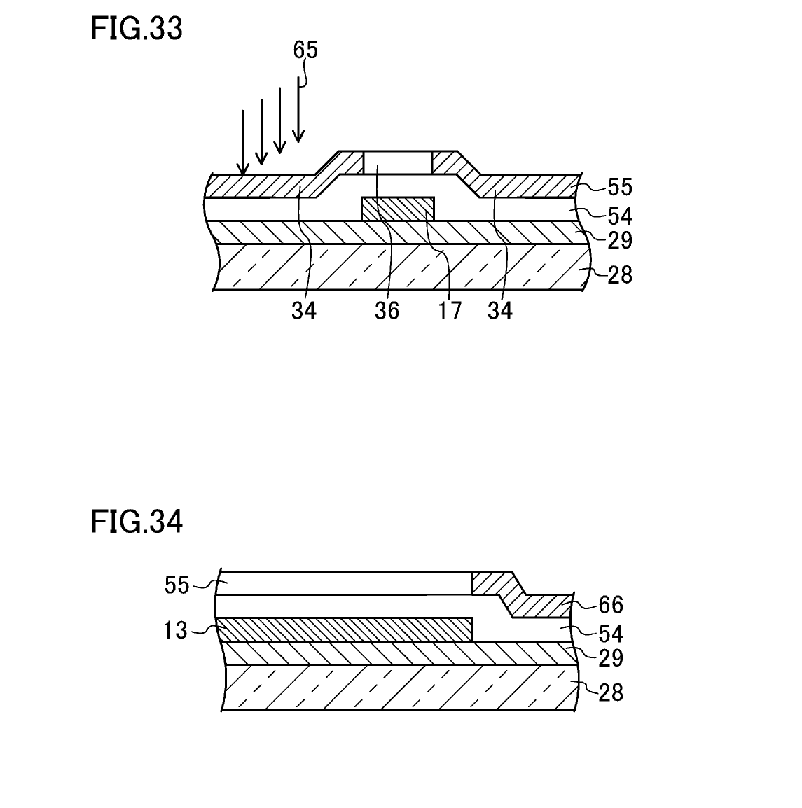

FIG. 31 is a cross-sectional view showing a semiconductor material layer into which an impurity element is implanted through a mask, in a region where a TFT of the second embodiment is to be formed. FIG. 32 is a cross-sectional view showing the semiconductor material layer into which an impurity element is implanted through a mask, in a region where an intersection portion is to be formed in the second embodiment. FIG. 33 is a cross-sectional view showing the semiconductor material layer irradiated with laser light. FIG. 34 is a cross-sectional view showing the semiconductor material layer included in the intersection portion.

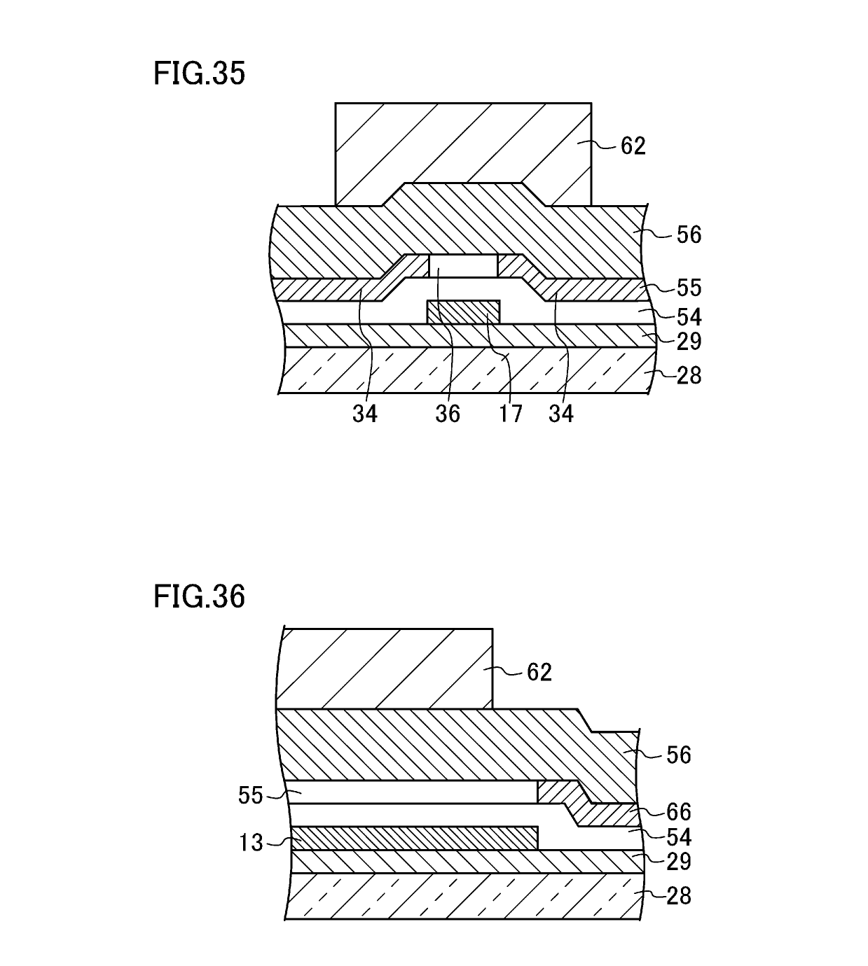

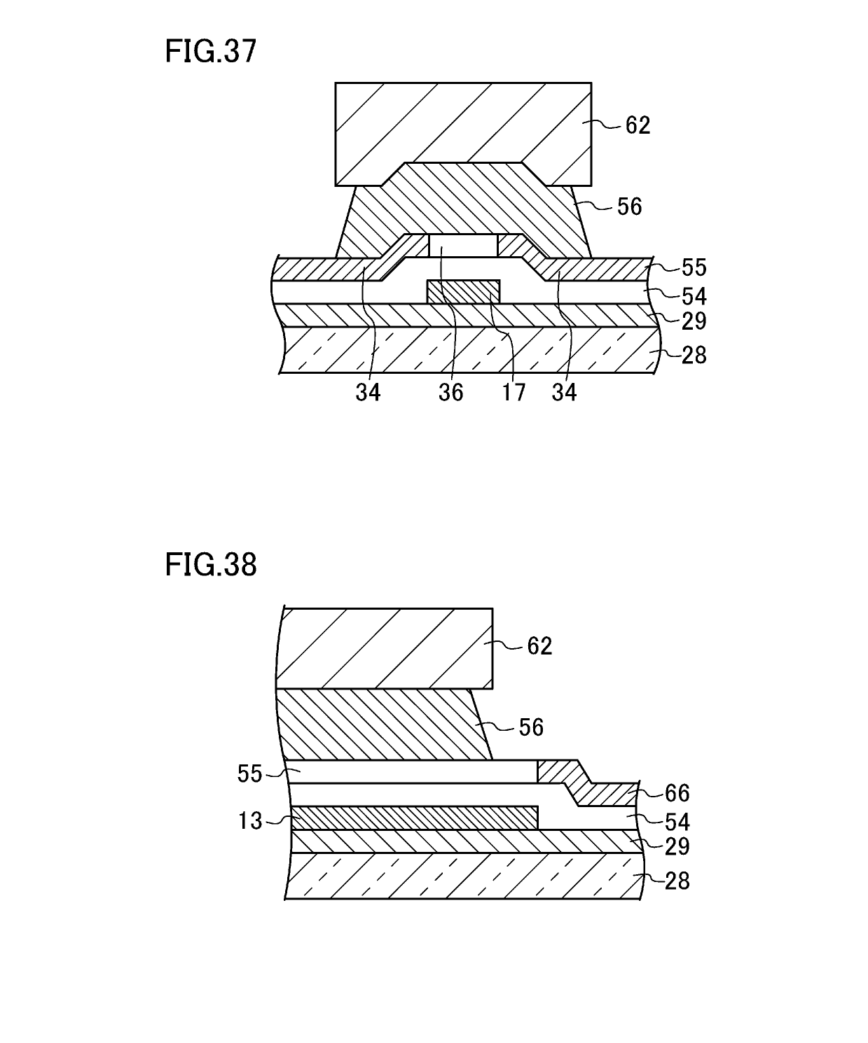

FIG. 35 is a cross-sectional view showing a second insulating material layer included in the TFT. FIG. 36 is a cross-sectional view showing the second insulating material layer included in the intersection portion. FIG. 37 is a cross-sectional view showing the second insulating material layer which is etched. FIG. 38 is a cross-sectional view showing the second insulating material layer which is etched.

In the first embodiment, when the second mask 61 for implanting impurity ions into the first semiconductor layer 31 is formed, the resist is exposed to light from the top surface (closer to the gate electrode 17) of the glass substrate 28. In this second embodiment, the resist is exposed to light from the bottom surface (further from the gate electrode 17) of the glass substrate 28.

Specifically, as shown in FIGS. 31 and 32, in the second embodiment, the resist formed on a surface of the semiconductor material layer 55 is exposed to light from the bottom surface of the glass substrate 28 to form the second mask 61, leaving the resist in a region facing the gate electrode 17 and a region facing the gate line 13. Thereafter, ions of an impurity element are implanted into the semiconductor material layer 55 exposed through the second mask 61. As a result, drain/source regions 34 are formed in the region where the TFT 16 is to be formed, and a high-concentration impurity region 66 is formed in the region where the intersection portion 51 is to be formed.

Next, as shown in FIGS. 33 and 34, after the second mask 61 is removed, the entire semiconductor material layer 55 is irradiated with laser light, such as excimer laser etc., resulting in polycrystallization of the semiconductor material layer 55. By the thermal treatment with laser light, the drain/source regions 34 and the high-concentration impurity region 66 can be thermally activated simultaneously with the polycrystallization of the semiconductor material layer 55. Therefore, also in this embodiment, a thermal treatment step of only activating the high-concentration impurity region can be removed.

Next, as shown in FIGS. 35 and 36, a second insulating material layer 56 is uniformly formed on a surface of the semiconductor material layer 55 by CVD etc. Next, a third mask 62 is formed on a surface of the second insulating material layer 56. The third mask 62 is formed in a region where the first semiconductor layer 31, the second semiconductor layer 32, and the third semiconductor layer 33 are to be formed, as viewed in the normal direction of the top surface of the glass substrate 28.

Thereafter, as shown in FIGS. 37 and 38, the second insulating material layer 56 is etched through the third mask 62. This etching is wet etching, which is isotropic etching. A lower end portion of the etched second insulating material layer 56 has the same width as that of the third mask 62, and has the same width as that of each of the first semiconductor layer 31, the second semiconductor layer 32, and the third semiconductor layer 33.

Next, as in the first embodiment, the semiconductor material layer 55, the first insulating material layer 54, and the second insulating material layer 56 are etched to form a first interlayer insulating film 41, a first semiconductor layer 31, a second interlayer insulating film 42, a second semiconductor layer 32, and a gate insulating film 30 as shown in FIGS. 21 and 22. Thus, as in the first embodiment, a TFT substrate 10 is manufactured, and thereafter, a liquid crystal display device 1 is manufactured.

Therefore, according to this second embodiment, advantages similar to those of the first embodiment can be obtained. In addition, when the second mask 61 is formed, a photo step is not required, and therefore, the number of steps can be further reduced.

### Third Embodiment of the Invention

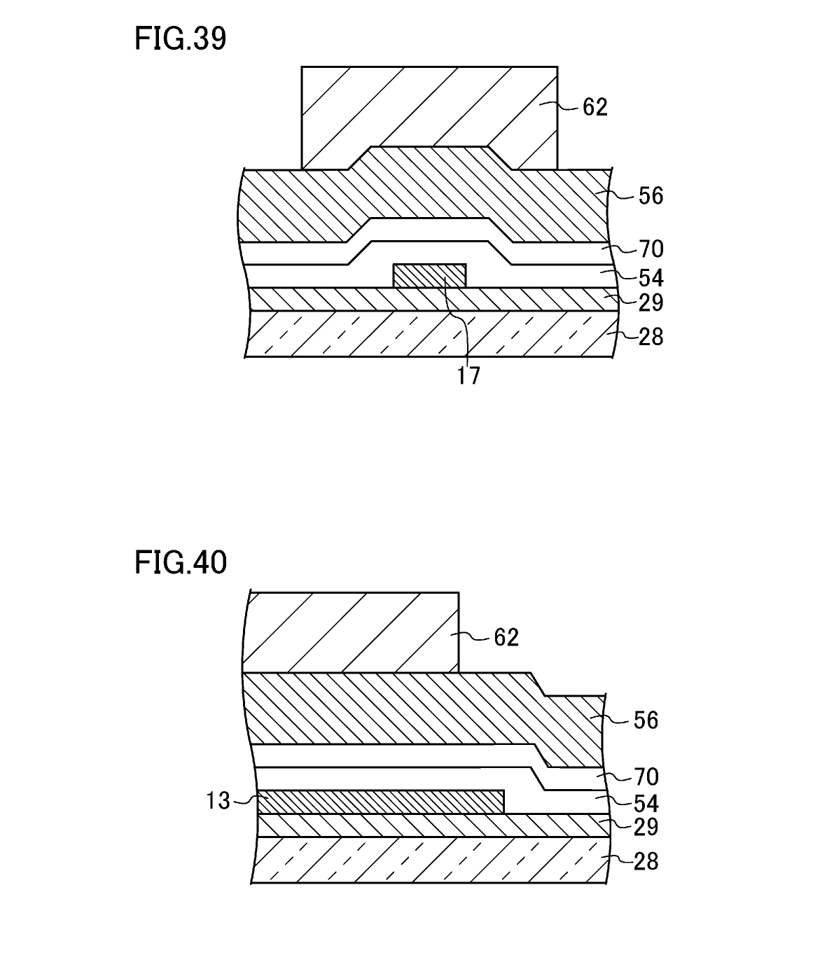

FIGS. 39-42 show a third embodiment of the present invention.

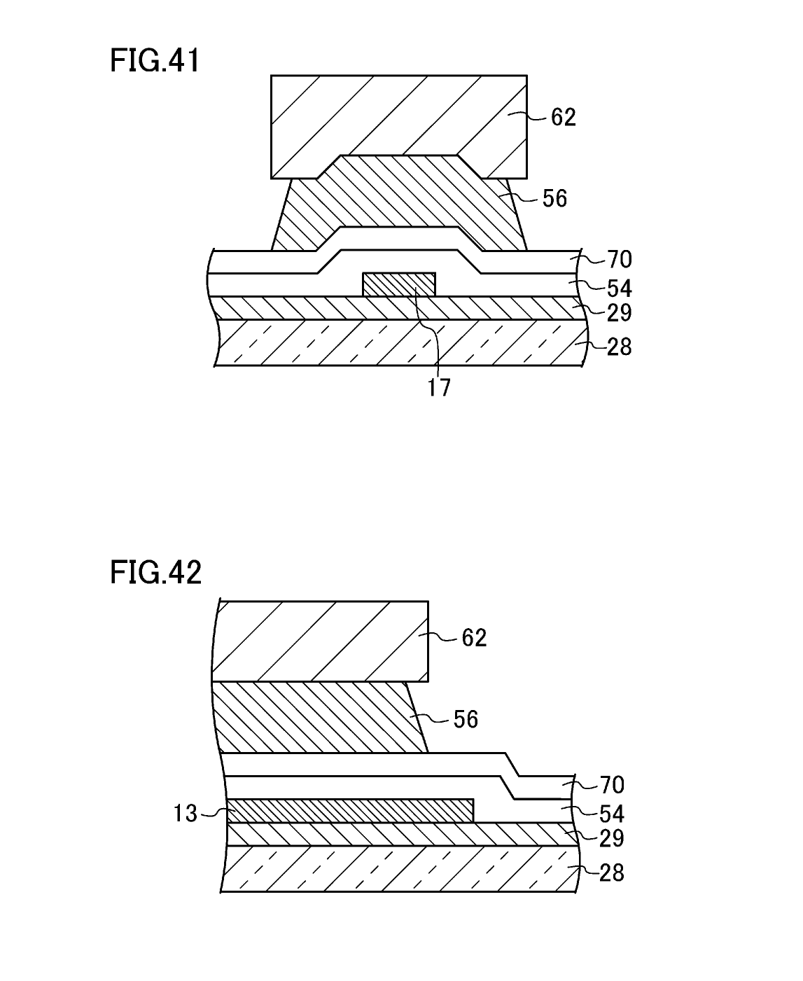

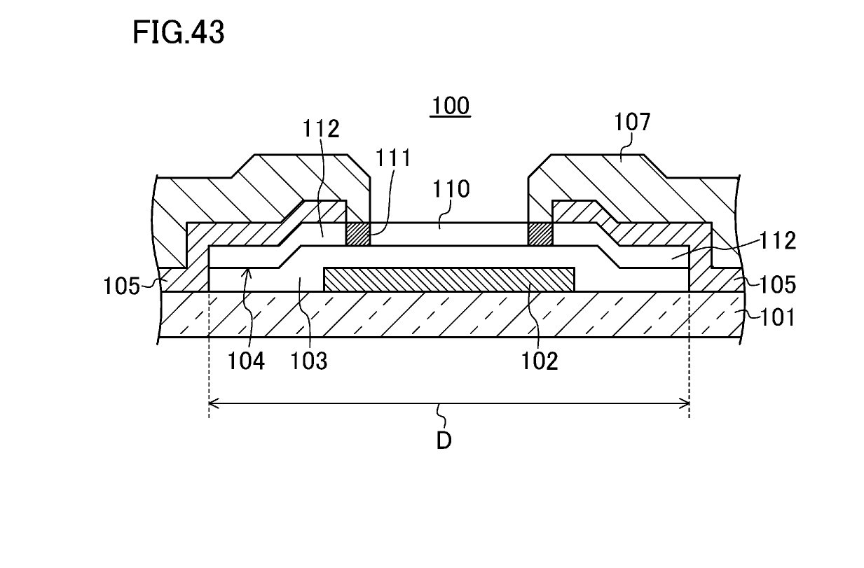

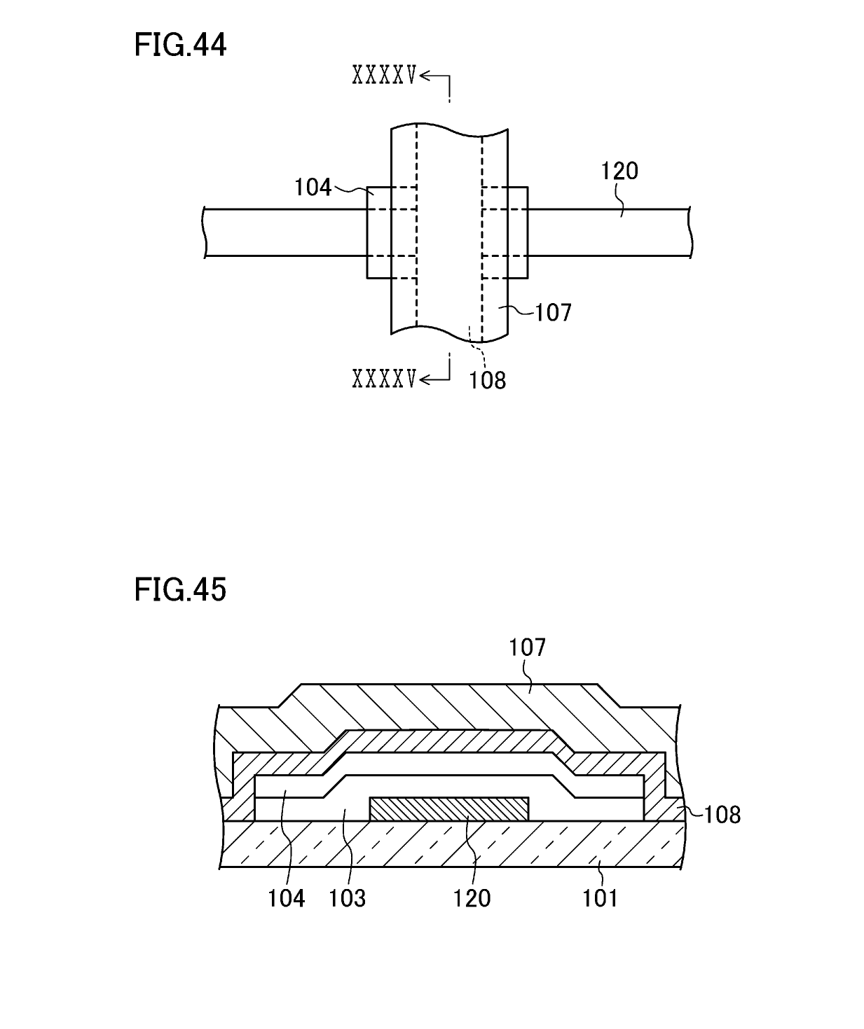

FIG. 39 is a cross-sectional view showing a second insulating material layer included in a TFT of the third embodiment. FIG. 40 is a cross-sectional view showing the second insulating material layer included in an intersection portion in the third embodiment. FIG. 41 is a cross-sectional view showing the second insulating material layer which is etched. FIG. 42 is a cross-sectional view showing the second insulating material layer which is etched.

In the first embodiment, a first semiconductor layer 31 etc. included in the TFT 16 are formed of a semiconductor layer of polysilicon. In the third embodiment, the semiconductor layer is formed of an oxide semiconductor In—Ga—ZnO₄ (IGZO) instead of polysilicon.

Specifically, in this embodiment, as shown in FIGS. 39 and 40, an IGZO layer 70 is formed on a surface of a first insulating material layer 54, and the second insulating material layer 56 is uniformly formed on a surface of the IGZO layer 70. Next, as in the first embodiment, after a third mask 62 is formed, as shown in FIGS. 41 and 42 the second insulating material layer 56 is wet-etched through the third mask 62.

Thereafter, as in the first embodiment, the IGZO layer 70, the first insulating material layer 54, and the second insulating material layer 56 are etched to form a first interlayer insulating film 41, a first semiconductor layer 31 of IGZO, a second interlayer insulating film 42, a second semiconductor layer 32 of IGZO, and a gate insulating film 30. Thus, as in the first embodiment, a TFT substrate 10 is manufactured, and thereafter, a liquid crystal display device 1 is manufactured.

Therefore, according to the third embodiment, advantages similar to those of the first embodiment can be obtained. In addition, an off leakage current in the TFT 16 can be significantly reduced, and a step of implanting ions of an impurity element into the first semiconductor layer 31 etc. is not required, whereby the number of steps can be further reduced.

### Other Embodiments

In the first to third embodiments, the TFT substrate 10 including the TFT 16 as a semiconductor device, and the liquid crystal display device, have been described. The present invention is not limited to this. The present invention is also applicable to semiconductor devices including other semiconductor elements, such as a diode etc., and other display devices, such as an organic EL display device etc.

### INDUSTRIAL APPLICABILITY

As described above, the present invention is useful for semiconductor devices and method for manufacturing the semiconductor devices, and liquid crystal display devices.

### DESCRIPTION OF REFERENCE CHARACTERS

1 LIQUID CRYSTAL DISPLAY DEVICE
10 TFT SUBSTRATE (ELEMENT SUBSTRATE)
11 COUNTER SUBSTRATE
13 GATE LINE
14 SOURCE LINE
17 GATE ELECTRODE
18 DRAIN/SOURCE ELECTRODE (ELECTRODE LAYER)
28 GLASS SUBSTRATE (INSULATING SUBSTRATE)
30 GATE INSULATING FILM
31 FIRST SEMICONDUCTOR LAYER
32 SECOND SEMICONDUCTOR LAYER
33 THIRD SEMICONDUCTOR LAYER
34 DRAIN/SOURCE REGION
36 CHANNEL REGION
41 FIRST INTERLAYER INSULATING FILM
42 SECOND INTERLAYER INSULATING FILM
54 FIRST INSULATING MATERIAL LAYER
55 SEMICONDUCTOR MATERIAL LAYER
56 SECOND INSULATING MATERIAL LAYER
61 SECOND MASK (RESIST PATTERN)

1. A semiconductor device comprising:
a gate electrode formed on an insulating substrate;
a gate insulating film covering the gate electrode;
a semiconductor layer formed on a surface of the gate insulating film and having a channel region facing the gate electrode; and
an electrode layer connected to the semiconductor layer,
wherein
an island-shaped interlayer insulating film covering the channel region is formed on a surface of the semiconductor layer,
an end portion of the interlayer insulating film is interposed between the semiconductor layer and the electrode layer,
outer edges of the interlayer insulating film are located further inside than respective corresponding outer edges of the semiconductor layer by the same width, as viewed in a normal direction of a surface of the insulating substrate, and
the electrode layer is connected to an end portion of the semiconductor layer.

2. The semiconductor device of claim 1, wherein
a width of the interlayer insulating film in a predetermined surface direction along the surface of the insulating substrate is greater than a width in the predetermined surface direction of the gate electrode.

3. The semiconductor device of claim 1 or 2, wherein
a width of the interlayer insulating film in a predetermined surface direction along the surface of the insulating substrate is greater than a width in the predetermined surface direction of the channel region.

4. The semiconductor device of claim 1, wherein
side surfaces of the gate insulating film and the semiconductor layer are on the same plane and are covered directly by the electrode layer.

5. The semiconductor device of claim 1, wherein
the semiconductor layer is formed of polysilicon.

6. The semiconductor device of claim 1, further comprising:
a holding capacitor element including a portion of the semiconductor layer and a capacitor line facing the portion of the semiconductor layer.

7. A method for manufacturing a semiconductor device comprising the steps of:
forming a gate electrode having a predetermined shape on an insulating substrate;
forming and stacking a first insulating material layer, a semiconductor material layer, and a second insulating material layer successively on the insulating substrate to cover the gate electrode;
forming a resist pattern on a surface of the second insulating material layer;
etching the second insulating material layer, the semiconductor material layer, and the first insulating material layer using the resist pattern as a mask, thereby forming a semiconductor layer of the semiconductor material layer having a predetermined shape, a gate insulating film of the first insulating material layer having the same shape as that of the semiconductor layer, and an interlayer insulating film of the second insulating material layer with an end portion of the semiconductor layer being exposed from the interlayer insulating film; and
forming an electrode layer covering a portion of the interlayer insulating film and a portion of the semiconductor layer with the electrode layer being connected to an end portion of the semiconductor layer.

8. The method of claim 7, wherein
a high-concentration impurity region is formed in the semiconductor material layer, and is crystallized by irradiation with laser light, and thereafter, is etched using the resist pattern as a mask.

9. The method of claim 7, wherein
a width of the interlayer insulating film in a predetermined surface direction along a surface of the insulating substrate is greater than a width in the predetermined surface direction of the gate electrode.

10. The method of claim 7, wherein
a width of the interlayer insulating film in a predetermined surface direction along a surface of the insulating substrate is greater than a width in the predetermined surface direction of the channel region.

11. The method of claim 7, wherein
side surfaces of the gate insulating film and the semiconductor layer are formed on the same plane and are covered directly by the electrode layer.

12. A liquid crystal display device including an element substrate on which a plurality of semiconductor elements are formed, a counter substrate facing the element substrate, and a liquid crystal layer provided between the counter substrate and the element substrate, wherein
the element substrate includes a gate electrode formed on an insulating substrate, a gate insulating film covering the gate electrode, a first semiconductor layer formed on a surface of the gate insulating film and having a channel region facing the gate electrode, and an electrode layer connected to the first semiconductor layer,
an island-shaped first interlayer insulating film covering the channel region is formed on a surface of the first semiconductor layer,
an end portion of the first interlayer insulating film is interposed between the first semiconductor layer and the electrode layer,
outer edges of the first interlayer insulating film are located further inside than respective corresponding outer edges of the first semiconductor layer by the same width, as viewed in a normal direction of a surface of the insulating substrate, and
the electrode layer is connected to an end portion of the first semiconductor layer.

13. The liquid crystal display device of claim 12, wherein
the element substrate includes a plurality of gate lines and a plurality of source lines intersecting the gate lines, and
a second semiconductor layer, and a second interlayer insulating film formed on a surface of the second semiconductor layer and formed of the same material as that of the first interlayer insulating film, are interposed between the gate lines and the source lines which intersect each other.
